(19) United States
(12) Patent Application Publication
(10) Pub. No.: US 2020/0176642 A1
(43) Pub. Date: Jun. 4, 2020

(54) LIGHT EMITTING DIODE AND METHOD OF MAKING SAME

(71) Applicant: ADVANCED OPTOELECTRONIC TECHNOLOGY, INC., Hsinchu Hsien (TW)

(72) Inventors: TZU-CHIEN HUNG, Hukou (TW); SHIUE-LUNG CHEN, Hsinchu (TW); CHIA-HUI SHEN, Hukou (TW)

(21) Appl. No.: 16/287,671

(22) Filed: Feb. 27, 2019

(30) Foreign Application Priority Data
Dec. 4, 2018 (CN) 201811475701.5

(51) Int. Cl. H01L 33/44; H01L 33/42; H01L 33/46; H01L 33/00; H01L 33/32

(52) U.S. Cl. CPC H01L 33/44; H01L 33/42; H01L 33/32; H01L 33/0075; H01L 33/46

(57) ABSTRACT

A light emitting diode includes a substrate, an epitaxial structure, a light absorbing material, an n-type electrode, and a p-type electrode. The epitaxial structure includes an n-type semiconductor layer, an active layer, and a p-type semiconductor layer formed sequentially on the substrate. The epitaxial structure includes a first recess and a second recess. The first recess extends toward the n-type semiconductor layer. The light absorbing material is received within the second recess. The n-type electrode is received within the first recess and forms an ohmic contact with the n-type semiconductor layer. The p-type electrode forms an ohmic contact with the p-type semiconductor layer. The p-type electrode, the light absorbing material, and the n-type electrode are sequentially spaced apart.

### FIELD

The subject matter herein generally relates to light emitting diodes and a method of making the light emitting diode.

### BACKGROUND

Nowadays, light emitting diode light sources are widely used in backlight modules. FIGS. 1A-1C show a light field distribution of a conventional light emitting diode. FIG. 1A shows a lambertian light field distribution. FIG. 1B shows a lateral light field distribution. FIG. 1C shows a concentrated light field distribution. It can be seen from FIG. 1A-1C that the existing light-emitting diode assembly has a concentrated shape and generates a regional bright spot and needs to be thickened by increasing a thickness of the optical diffuser or increasing a density of the light-emitting diode assembly. This is not conducive to thinning of the planar light source module and thus increases a manufacturing cost.

### BRIEF DESCRIPTION OF THE DRAWINGS

Implementations of the present disclosure will now be described, by way of embodiments only, with reference to the attached figures.

FIGS. 1A-1C are light field distributions of a conventional light emitting diode.

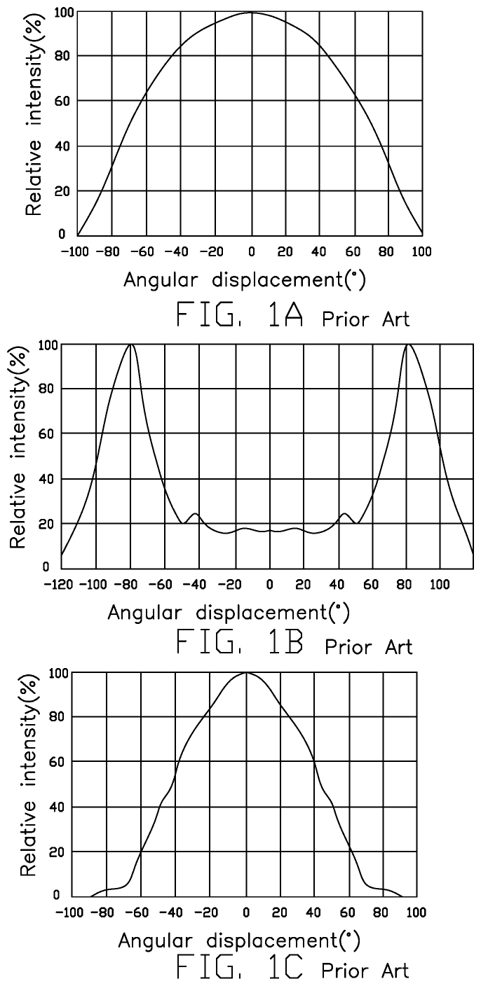

FIG. 2 is a cross-sectional view of an embodiment of a substrate and an epitaxial structure of a light emitting diode.

FIG. 3 is a cross-sectional view showing a first recess and a second recess formed in the epitaxial structure in FIG. 2.

FIG. 4 is a cross-sectional view showing an insulating layer formed on the epitaxial structure in FIG. 3.

FIG. 5 is a cross-sectional view showing a transparent current diffusion layer formed on the epitaxial structure in FIG. 4.

FIG. 6 is a cross-sectional view showing a passivation layer formed on the transparent current diffusion layer in FIG. 5.

FIG. 7 is a cross-sectional view showing the second recess in FIG. 6 filled with a light absorbing material.

FIG. 8 is a cross-sectional view showing a reflective layer formed on the passivation layer in FIG. 7.

FIG. 9 is a cross-sectional view showing a first blind hole and a second blind hole formed in the structure in FIG. 8.

FIG. 10 is a cross-sectional view of an embodiment of a light emitting diode.

FIG. 11 is a diagram showing a light field distribution of the light emitting diode in FIG. 11.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as coupled, whether directly or indirectly through intervening components, and is not necessarily limited to physical connections. The connection can be such that the objects are permanently coupled or releasably coupled. The term “comprising” means “including, but not necessarily limited to”; it specifically indicates open-ended inclusion or membership in a so-described combination, group, series and the like.

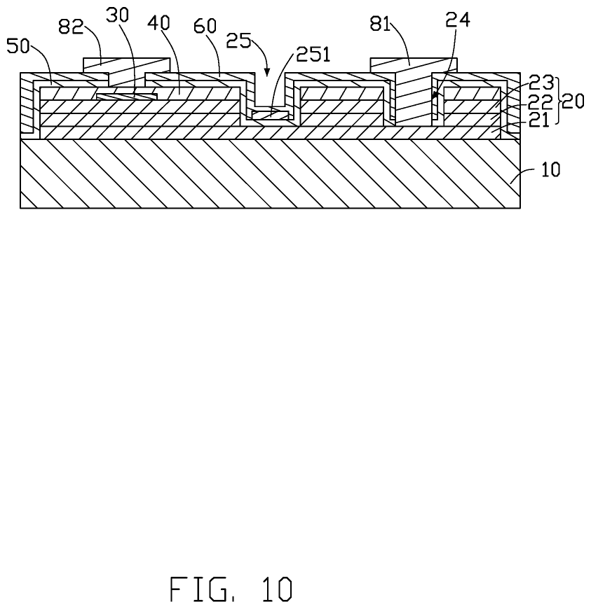

FIG. 10 shows an embodiment of a light emitting diode including a substrate 10, an epitaxial structure 20 formed on the substrate 10, an n-type electrode 81 and a p-type electrode 82 formed on the epitaxial structure 20, and a light absorbing material 251 formed between the n-type electrode 81 and the p-type electrode 82.

The substrate 10 may be composed of sapphire, silicon carbide (SiC), silicon (Si), gallium arsenide (GaAs), lithium metaaluminate (LiAlO₂), magnesium oxide (MgO), zinc oxide (ZnO), gallium nitride (GaN), aluminum nitride (AlN), indium nitride (InN), or other single crystal substrate.

The epitaxial structure 20 includes an n-type semiconductor layer 21, an active layer 22, and a p-type semiconductor layer 23 sequentially formed on the substrate 10.

The n-type semiconductor layer 21, the active layer 22, and the p-type semiconductor layer 23 may be a single layer or a multilayer structure made of material selected from group III nitride semiconductor material. Among them, the group III element may be an element such as Al, Ga, or In. The n-type semiconductor layer 21, the active layer 22, and the p-type semiconductor layer 23 may be n-type gallium nitride, indium gallium nitride (InGaN), and p-type gallium nitride, respectively.

The epitaxial structure 20 includes a first recess 24 and a second recess 25. The first recess 24 extends to the n-type semiconductor layer 21.

In one embodiment, a depth of the second recess 25 is 1 micrometer, but is not limited thereto.

The light absorbing material 251 is embedded in the second recess 25. The light absorbing material 251 may be chromium (Cr), black photoresist (black glue) or other light absorbing material.

A thickness of the light absorbing material 251 is between 100 nm to 500 nm.

The n-type electrode 81 is received in the first recess 24 and is in ohmic contact with the n-type semiconductor layer 21.

The p-type electrode 82 forms an ohmic contact with the p-type semiconductor layer 23. The p-type electrode 82, the light absorbing material 251, and the n-type electrode 81 are sequentially spaced at intervals.

In one embodiment, the light emitting diode further includes an insulating layer 30. The insulating layer 30 is arranged on a side of the p-type electrode 82 facing the substrate 10. The insulating layer 30 blocks an electric current from diffusing downward toward the p-type electrode 82 to prevent the emitted light from being blocked by the p-type electrode 82. The insulating layer 30 may be made of at least one of silicon dioxide (SiO₂), aluminum nitride (AlN), and silicon nitride compound (SixNy). In one embodiment, the insulating layer 30 is made of silicon dioxide (SiO₂).

In one embodiment, the light emitting diode further includes a transparent current diffusion layer 40. The transparent current diffusion layer 40 covers the p-type semiconductor layer 23 to enhance electric current diffusion, thereby improving light extraction efficiency. Moreover, since the transparent current diffusion layer 40 is transparent, it does not block the light emitted from the light emitting diode.

In one embodiment, the light emitting diode further includes a passivation layer 50. The passivation layer 50 covers an outer side of the n-type semiconductor layer 21 and the transparent current diffusion layer 40. The passivation layer 50 protects the light-emitting area from damage caused by external contamination and interference. The passivation layer 50 may be made of silicon dioxide (SiO₂) or silicon nitride (Si₃N₄).

In one embodiment, the light emitting diode further includes a reflective layer 60. The reflective layer 60 covers an outer side of the passivation layer 50. The reflective layer 60 reflects light emitted by the light emitting diode and irradiated onto the reflective layer 60, thereby reducing side light emission of the diode to improve light extraction efficiency.

In one embodiment, a surface area of a light emitting surface of the light emitting diode is 130 μm by 250 μm. A cross-sectional area of each of the n-type electrode 81 and the p-type electrode 82 is 50 μm by 90 μm. A cross-sectional area of the second recess 25 is 25 μm by 25 μm. A thickness of the substrate 10 is 90 μm. In other embodiments, the above parameters may be adjusted as needed.

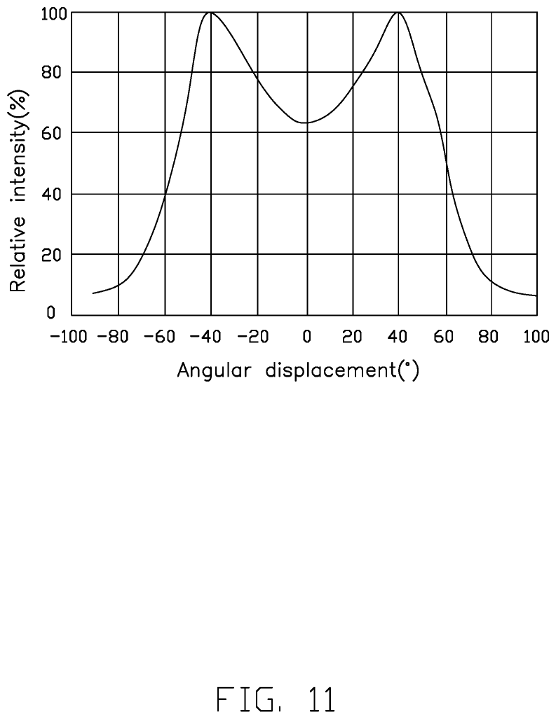

The second recess 25 is arranged between the n-type electrode 81 and the p-type electrode 82. The light absorbing material 251 is filled into the second recess 25. FIG. 11 shows a light field distribution of the light emitting diode. The second recess 25 forms a central dark region, and the light absorbing material 251 is capable of absorbing light to reduce reflection and achieve a batwing light field. Therefore, the light emitting diode has an advantage of uniform light emission.

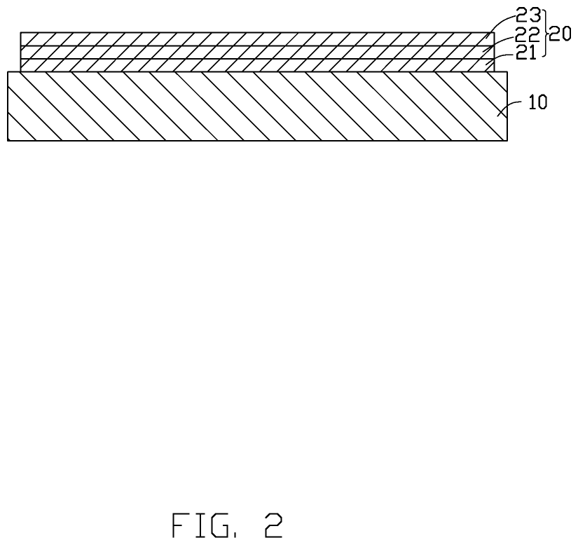

FIGS. 2-10 show an embodiment of a method for making a light emitting diode, which includes the following steps.

As shown in FIG. 2, a substrate 10 is provided, and an epitaxial structure 20 is formed on the substrate 10. The epitaxial structure 20 includes an n-type semiconductor layer 21, an active layer 22, and a p-type semiconductor layer 23 sequentially formed on the substrate 10.

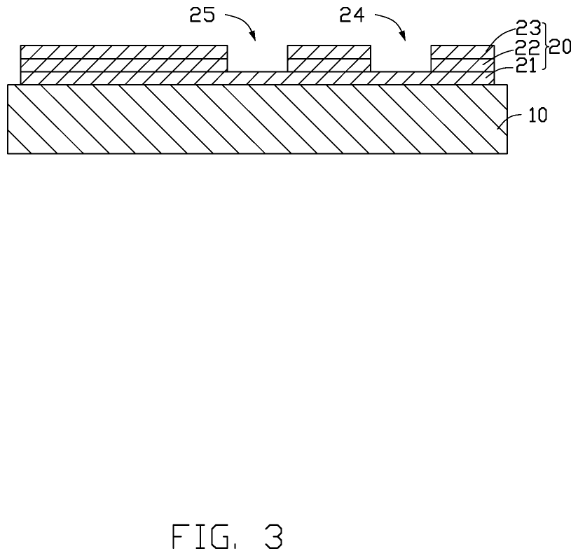

As shown in FIG. 3, the epitaxial structure 20 is etched to form a first recess 24 and a second recess 25. The first recess 24 exposes the n-type semiconductor layer 21.

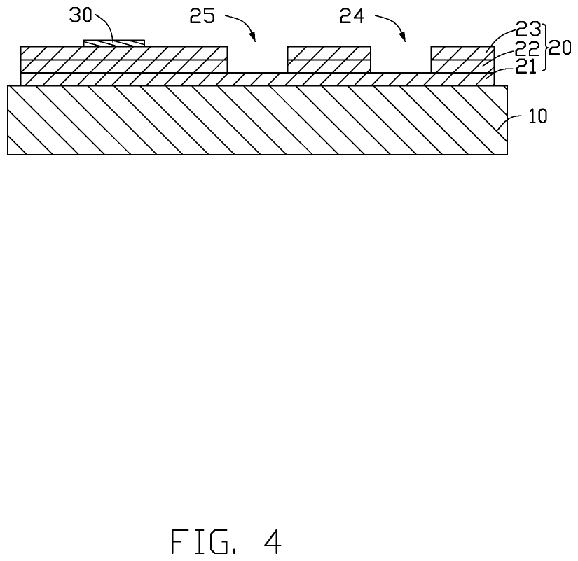

As shown in FIG. 4, an insulating layer 30 is formed on a portion of the p-type semiconductor layer 23. The insulating layer 30, the second recess 25, and the first recess 24 are sequentially spaced apart.

The insulating layer 30 may be made of at least one of silicon dioxide (SiO₂), aluminum nitride (AlN), and silicon nitride compound (SixNy). In one embodiment, the insulating layer 30 is made of silica.

In other embodiments, the insulating layer 30 may be omitted.

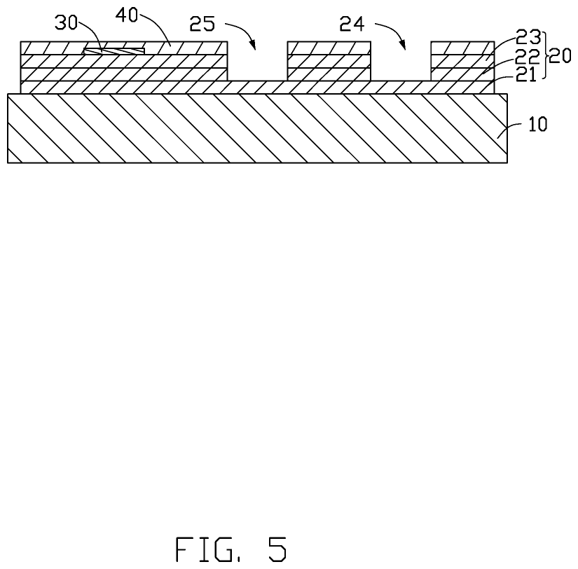

As shown in FIG. 5, a transparent current diffusion layer 40 is formed on the insulating layer 30 and the p-type semiconductor layer 23.

The transparent current diffusion layer 40 is formed by physical vapor deposition such as vapor deposition or sputtering, and a material thereof may be indium tin oxide (ITO), indium zinc oxide (IZO), aluminum zinc oxide (AZO), gallium zinc oxide (GZO), gallium indium oxide (GIO), or indium gallium zinc oxide (IGZO).

In other embodiments, the transparent current diffusion layer 40 may be omitted.

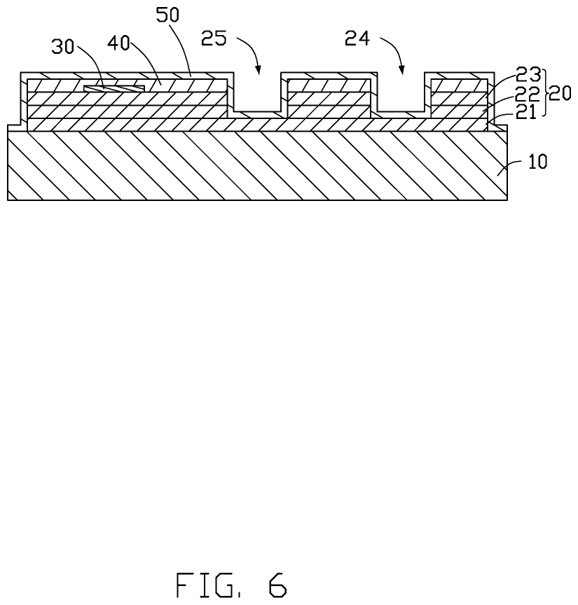

As shown in FIG. 6, a passivation layer 50 is formed on the transparent current diffusion layer 40, the first recess 24 and the second recess 25.

The passivation layer 50 can be composed of silicon dioxide (SiO₂) or silicon nitride (SiN) and formed by chemical vapor deposition to protect crystallite properties of the LED and prevent external electrical or physical interference of the LED.

In other embodiments, the passivation layer 50 may be omitted.

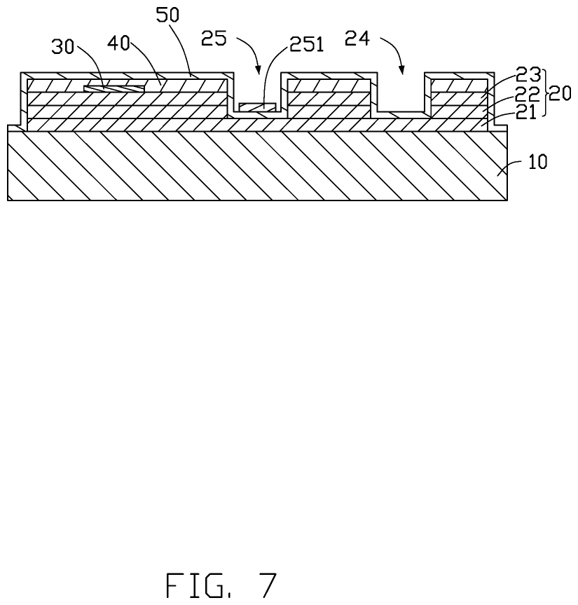

As shown in FIG. 7, the second recess 25 is filled in with the light absorbing material 251.

The light absorbing material 251 may be chromium (Cr), black photoresist (black glue) or the like. A thickness of the light absorbing material 251 is 100 nm to 500 nm.

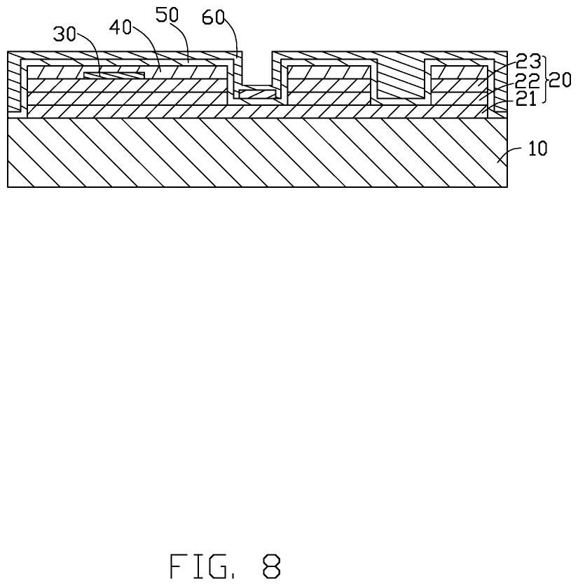

As shown in FIG. 8, a reflective layer 60 is formed on the light absorbing material 251 and the passivation layer 50.

In one embodiment, the reflective layer 60 is formed by vapor deposition. The reflective layer 60 is made of metal such as silver or aluminum. The reflective layer 60 reflects light emitted by the light emitting diode and irradiated onto the reflective layer 60, thereby reducing side light emission of the diode to improve light extraction efficiency.

In other embodiments, the reflective layer 60 may be formed before then step 6 is performed before filling in the light absorbing material.

In other embodiments, the reflective layer 60 may be omitted.

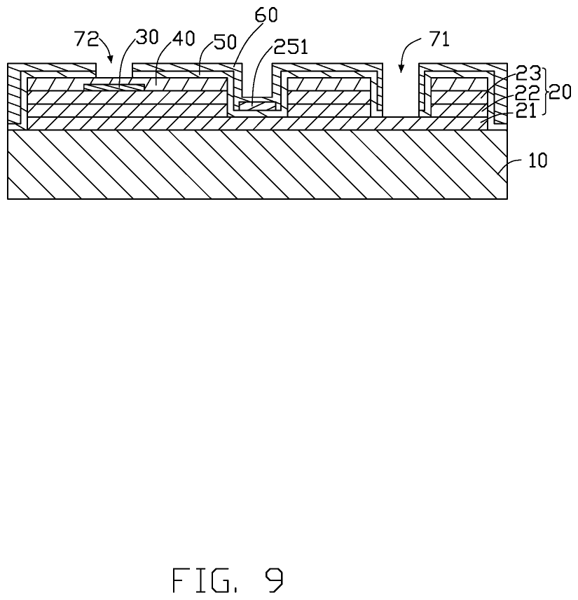

As shown in FIG. 9, portions of the reflective layer 60 and the passivation layer 50 aligned with the first recess 24 and the insulating layer 30 are etched to obtain a first blind hole 71 and a second blind hole 72, respectively.

The first blind hole 71 extends to the n-type semiconductor layer 21, and the second blind hole 72 extends to the transparent current diffusion layer 40.

As shown in FIG. 10, an n-type electrode 81 is formed in upper and lower regions of the first blind hole 71, and a p-type electrode 82 is formed in upper and lower regions of the second blind hole 72. The n-type electrode 81 is electrically coupled to the n-type semiconductor layer 21, and the p-type electrode 82 is electrically coupled to the transparent current diffusion layer 40.

The n-type electrode 81 may be composed of at least one of titanium/aluminum/titanium/gold alloy (Ti/Al/Ti/Au), chrome/gold alloy (Cr/Au), or lead/gold alloy (Pd/Au). The p-type electrode 82 may be composed of at least one of nickel gold alloy (Ni/Au), platinum gold alloy (Pt/Au), tungsten (W), chromium gold alloy (Cr/Au), or palladium (Pd).

In other embodiments, if the passivation layer 50 and the reflective layer 60 are omitted, the first blind hole 71 and the second blind hole 72 are omitted, such that the n-type electrode 81 and the p-type electrode 82 are directly electrically coupled to the n-type semiconductor layer 21 and the transparent current diffusion layer 40, respectively.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

1. A light emitting diode comprising:
a substrate;
an epitaxial structure comprising an n-type semiconductor layer, an active layer, and a p-type semiconductor layer formed sequentially on the substrate, wherein the epitaxial structure comprises a first recess and a second recess, and the first recess extends toward the n-type semiconductor layer;
a light absorbing material received within the second recess;
an n-type electrode received within the first recess and forming an ohmic contact with the n-type semiconductor layer; and
a p-type electrode forming an ohmic contact with the p-type semiconductor layer,
wherein the p-type electrode, the light absorbing material, and the n-type electrode are sequentially spaced apart.

2. The light emitting diode of claim 1, wherein the light absorbing material is chromium or black photoresist.

3. The light emitting diode of claim 1 further comprising an insulating layer arranged on a side of the p-type electrode facing the substrate.

4. The light emitting diode of claim 1 further comprising a transparent current diffusion layer covering the p-type semiconductor layer.

5. The light emitting diode of claim 1 further comprising a passivation layer covering the n-type semiconductor layer and the p-type semiconductor layer.

6. The light emitting diode of claim 1 further comprising a reflective layer covering the n-type semiconductor layer and the p-type semiconductor layer.

7. A method of making a light emitting diode, the method comprising:
providing a substrate and forming an epitaxial layer on the substrate, wherein the epitaxial layer comprises an n-type semiconductor layer, an active layer, and a p-type semiconductor layer formed in sequence;
etching the epitaxial layer to form a first recess and a second recess, wherein the first recess exposes the n-type semiconductor layer;
filling in the second recess with light absorbing material; and
forming an n-type electrode in the first recess, and forming a p-type electrode on the p-type semiconductor layer, wherein the n-type electrode is electrically coupled to the n-type semiconductor layer, and the P-type electrode is electrically coupled to the p-type semiconductor layer,
wherein the p-type electrode, the light absorbing material, and the n-type electrode are sequentially spaced apart.

8. The method of claim 7 further comprising:
forming an insulating layer on a portion of the p-type semiconductor layer after forming the first recess and the second recess and before filling in the second recess with the light absorbing material, wherein:
the insulating layer, the second recess, and the first recess are sequentially spaced apart; and
the p-type electrode is aligned with the insulating layer.

9. The method of claim 8 further comprising:
forming a transparent current diffusion layer on the insulating layer and the p-type semiconductor layer after forming the insulating layer and before filling in the second recess with the light absorbing material.

10. The method of claim 7, wherein the light absorbing material is chromium or black photoresist.
